(19) United States
(12) Patent Application Publication
(10) Pub. No.: US 2006/0006472 A1
(43) Pub. Date: Jan. 12, 2006

(54) Phase change memory with extra-small resistors

(76) Inventor: Hai Jiang, Fremont, CA (US)

Correspondence Address: Hai Jiang, 6296 Hansen Dr., Pleasanton, CA, 94566, US

(21) Appl. No.: 11/194,279

(22) Filed: Aug. 1, 2005

Related U.S. Application Data
(63) Continuation of application No. 10/453,325, filed on Jun. 3, 2003.

(51) Int. Cl. H01L 23/62

(52) U.S. Cl. 257/358

(57) ABSTRACT

A phase change memory cell comprises of multiple resistors. In one design, the resistor layer is a layer with a plurality of resistors embedded in an insulator layer which is sandwiched between the electrodes. In the other design, a combination of a heater layer with a plurality of heaters and a layer of phase change material constitutes the resistor sandwiched a pair of electrodes. The resistor or heater can be easily made in nano-size.

### CROSS-REFERENCE TO RELATED APPLICATIONS

This is a continuation of application Ser. No. 10/453/325, filed on Jun. 03, 2003, now abandoned.

### FEDERALLY SPONSORED RESEARCH

none

### FIELD OF THE INVENTION

This invention relates generally to electronic memories that use phase change materials, and particularly to the structure, materials, and fabrication of the memory cell.

### THE BACKGROUND OF THE INVENTION

The phase change memory is a kind of non-volatile memory that uses phase change material to store the information. Typically, a phase change memory cell consists of a resistor located between two electrodes. The resistor is made of phase change material and can be switched in different resistance values corresponding to different states of the phase change material. The states may be called the amorphous or crystalline states. The amorphous state generally exhibits higher resistivity than the crystalline state. The state of phase change material is changed by the resistive heating from the programming current.

A variety of phase change materials are known. Generally, chalcogenide materials containing one or more elements from Column VI of the period table are used as phase change material in the memory application. One particularly suitable group of alloys is the GeSbTe.

There are two designs of phase change memory. In one design, the phase change material is formed within a hole through an insulator. The phase change material may be coupled to upper and lower electrodes on either end of the hole and forms a resistor.

In another design, a heater is formed within a hole through an insulator. A layer of phase change material is then placed above the heater. The heater and phase change material are contacted with lower and upper electrodes, respectively. The portion of phase change material adjacent to the heater is called active region and change to amorphous or crystalline state after programming current flow through the heater. Therefore, the phase change material in the active region basically determines the resistance of the memory cell. In this case, the active region forms a resistor since the heater is made of conductive material.

As mentioned above, the change of the resistor's resistance in the phase change memory is accomplished by heating the phase change material. The power needed to change the resistor's resistance is basically determined by the volume of the phase change material. Bigger the volume of phase change material, the higher the power needed. To minimize the power consumption, the reduction of the hole size is needed.

The hole was normally formed by the photolithography and etching. There have been some efforts in making small hole to decrease the volume of the phase change material. However most of these efforts are limited either by the resolution of the photolithography process or involve some complicated processes such as chemical mechanical planarization (CMP). The advantage of smaller resistor is not only the lower power consumption, but also that the making much faster and higher density memory becomes possible. Therefore there is a need to seek an economic, effective method to make small hole or resistor.

It is well known that when two different and unmixable materials are co-deposited onto a substrate they normally form a composite thin film with two separated phases containing each material. In some cases, one material may form the small particles embedded in another material, such as in the case of Fe/SiO₂ composite thin film (J. Applied Physics, Vol 84, 1998, p 5693). This thin film technology provides a way to fabricate small resistor or heater for the phase change memory application. A phase change memory cell structure with multiple resistors is presented in this invention. Although the memory cell consists of multiple resistors, the overall volume of phase change material can be much smaller than in the conventional phase change memory and process is also much simpler.

### SUMMARY OF THE INVENTION

An object of the present invention is to provide a new phase change memory structure with extremely small resistor or heater. It is also an object of the present invention to provide some methods to make this memory structure. The extremely small size of the resistor or heater makes this memory have a good scalability and possibility to make high density memory.

### BRIEF DESCRIPTION OF THE DRAWINGS

FIG. 1 is a cross sectional view illustrating a memory cell structure with multiple resistors.

FIG. 2 is a simplified and enlarged perspective view illustrating the structure of resistor layer.

FIG. 3 is a cross sectional view illustrating a memory cell structure with a lamination of resistor layer and conductive layer.

FIG. 4 is a cross sectional view illustrating a memory cell structure with multiple heaters.

FIG. 5 is a cross sectional view illustrating a memory cell structure with a lamination of heater, phase change material and conductive layers.

### DETAILED DESCRIPTION OF THE INVENTION

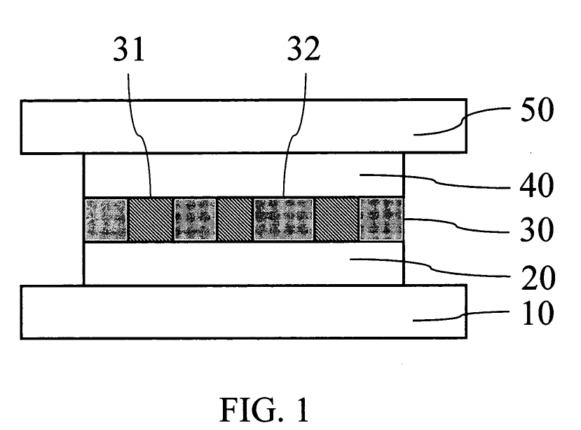

FIG. 1 is a cross sectional view illustrating a memory cell structure with multiple resistors. The memory cell comprises of 3 layers: electrode layers 20 and 40, resistor layer 30. The resistor layer 30 is a layer where some resistors 31 with size of about 1 nm to several tens nm (1 nm=10⁻⁹ m) embedded uniformly in a high resistance matrix 32. The electrode layers 20 and 40 are made of conductive material. The whole memory cell is located between the address lines 10 and 50.

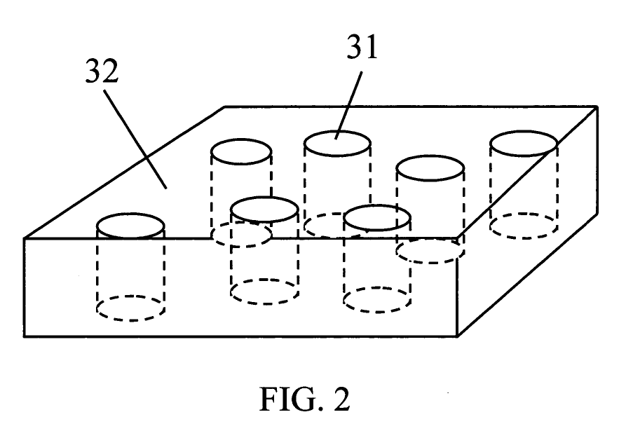

FIG. 2 shows a simplified and enlarged perspective view illustrating the structure of resistor layer. The size of resistor 31 is defined herein as the diameter of the resistor, or its “characteristic dimension” which is equivalent to the diameter where the resistors are not cylindrically shaped. The resistor is made of phase change material and has much smaller resisitivity than the matrix material so that current mainly flows through the resistors 31. The resistors 31 contact with upper electrode 40 and lower electrode 20. The thickness of resistor layer 30, i.e., the height of the resistor 31, is in the same order of its diameter.

The resistor layer 30 can be made by co-deposition of a phase change material and the high resistivity materials. The phase change material forms approximately cylinder-shaped nano-size particles embedded in the high resistivity matrix. The resistor layer 30 can be made by various thin film deposition methods such as sputtering, evaporation, or the chemical vapor deposition (CVD). The phase change material and high resistive material were chosen such that they are not mixable. By optimizing the deposition conditions and selecting suitable materials, a well-defined resistor 31 with desired size can be formed and embed uniformly in the high resistive matrix. To ensure the resistor is isolated by high resistive material, the volume ratio of phase change material and high resistive material should be less than 3/1, typically, in the range of 1/1˜1/1000.

As mentioned above, the phase change material and high resistive matrix material were chosen such that they are not mixable. Selectable materials with this combination are extensively. The oxide, nitride, boride, carbide, boron, silicon, carbon, carboxynitride or the mixture of these materials are the good candidates as high resistive material, while most semiconductors, alloys, more preferably chalcogenide, are the good candidates as the resistor material.

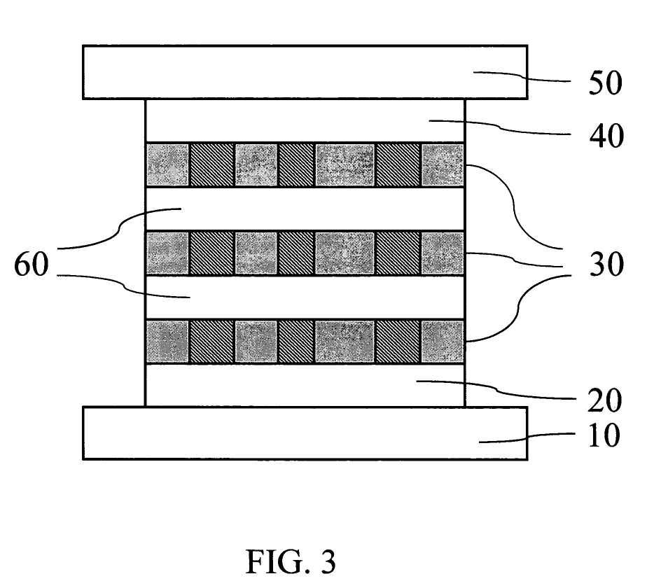

The resistance of the memory cell can be changed by using a lamination of resistor layer and conductive layer. FIG. 3 shows a memory cell structure with lamination of resistor layer 30 and conductive layer 60. The advantages of laminated memory cell are improved uniformity of the resistance of each memory cell and to obtain a desired resistance value. These advantages are especially of importance when the memory element size becomes substantially small for the extra-high density memory. Since the number of the resistor in a single resistor layer decreases with memory element size, the less is the number of the resistors, the poorer is the uniformity of the resistance of the memory cell. So there may be a need to have certain number of resistors in a single memory cell to ensure a uniform resistance distribution among the memory cells.

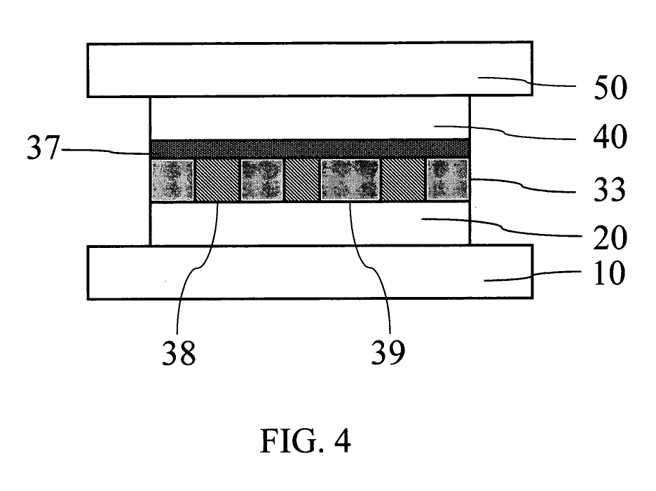

FIG. 4 is a cross sectional view illustrating a memory cell structure with a multiple small heaters. The structure consists of a heater layer 33 and a phase change material layer 37. The heater layer 33 is layer with multiple small heaters 38 embedded in a high resistivity matrix 39. The heater 38 is made of a conductive material and formed in approximately cylinder shape. Since the heater has much smaller resistivity than the matrix material, the programming current mainly flows through the heaters and thus can heat the portion of phase change layer 37 adjacent to the heater.

Making the heater layer is similar to the resistor layer except that the phase change material is replaced by a conductive material.

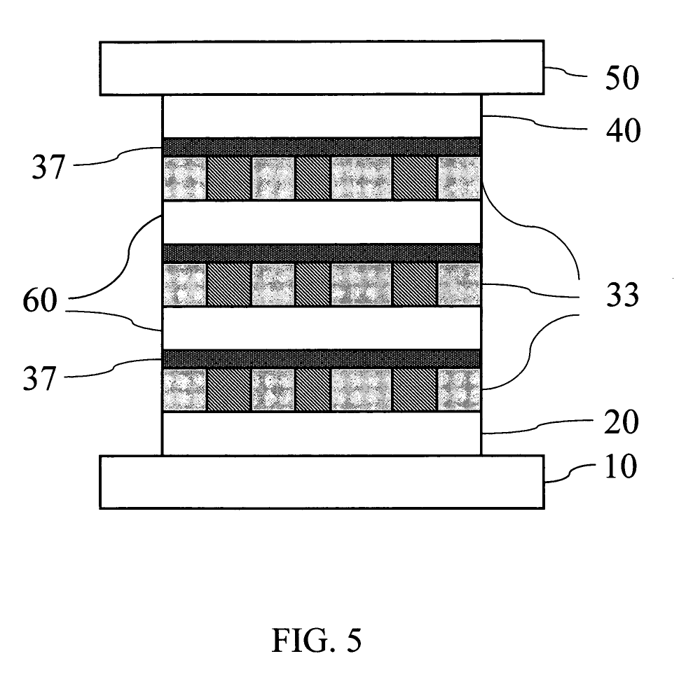

Like the memory cell with multiple resistors, this memory cell can also be made by the lamination of heater, phase change material and conductive layers. FIG. 5 shows the phase change memory cell with a lamination of heater layer 33, phase change material layer 37 and conductive layer 60.

What is claim is:

1. Memory device comprising:
a. a resistor layer, or
b. a lamination of said resistor layer and a conductive layer.

2. The device of claim 1 wherein said resistor layer is a layer with a plurality of resistors embedded in an insulator layer.

3. The device of claim 1 wherein said resistor is made of phase change material.

4. The device of claim 1 wherein the size of the resistor is in the range of about 1.0-50 nm.

5. Memory device comprising
a. a heater layer and a phase change material layer, or
b. a lamination of said heater layer, said phase change material layer and a conductive layer.

6. Claim 5 wherein said heater layer is a layer with a plurality of low resistance small particles embedded in a high resistance layer.

7. Claim 6 wherein the size of said small particles have a size in the range of about 1.0-50 nm.
